(19) United States
(12) Patent Application Publication
(10) Pub. No.: US 2023/0387175 A1
(43) Pub. Date: Nov. 30, 2023

(54) IMAGING APPARATUS AND INFORMATION PROCESSING APPARATUS

(71) Applicant: SONY SEMICONDUCTOR SOLUTIONS CORPORATION, KANAGAWA (JP)

(72) Inventor: YASUNORI TSUKUDA, KANAGAWA (JP)

(21) Appl. No.: 18/249,356

(22) PCT Filed: Oct. 1, 2021
(86) PCT No.: PCT/JP2021/036501

§ 371 Date: Apr. 17, 2023

(30) Foreign Application Priority Data
Nov. 2, 2020 (JP) 2020-183642

(51) Int. Cl. H01L 27/146

(52) U.S. Cl. CPC H01L 27/14647; H01L 27/14612; H04N 25/78

(57) ABSTRACT

An imaging apparatus according to the present technology includes a plurality of photoelectric conversion units, each including a photoelectric conversion element that performs photoelectric conversion with light in a different wavelength region, the photoelectric conversion units being stacked in a light incident direction, and a charge holding unit that holds charges accumulated in the photoelectric conversion element in the different photoelectric conversion units.

### TECHNICAL FIELD

The present technology relates to an imaging apparatus and an information processing apparatus, and particularly relates to a technical field of an imaging apparatus including stacked photoelectric conversion units and an information processing apparatus.

### BACKGROUND ART

There has been proposed an imaging apparatus including a solid-state image sensor in which photoelectric conversion units are stacked. In such an imaging apparatus, a circuit that reads a signal charge generated by photoelectric conversion in each photoelectric conversion element of the photoelectric conversion unit is provided for each photoelectric conversion element (refer to Patent Document 1 below, for example).

### CITATION LIST

### Patent Document

Patent Document 1: Japanese Patent Application Laid-Open No. 2015-128131

### SUMMARY OF THE INVENTION

### Problems to be Solved by the Invention

In an imaging apparatus described in Patent Document 1, a floating diffusion as a charge holding unit that holds signal charges is provided for each photoelectric conversion element of stacked photoelectric conversion units. However, a configuration including a charge holding unit provided for each photoelectric conversion element in the stacked photoelectric conversion units is complex.

The present technology has been made in view of the circumstances described above, and an object thereof is to simplify a configuration.

### Solutions to Problems

An imaging apparatus according to the present technology includes a plurality of photoelectric conversion units, each including a photoelectric conversion element that performs photoelectric conversion with light in a different wavelength region, the photoelectric conversion units being stacked in a light incident direction, and a charge holding unit that holds charges accumulated in the photoelectric conversion elements in different the photoelectric conversion units.

This allows to share and use the charge holding unit for the photoelectric conversion elements in the different stacked photoelectric conversion units.

The imaging apparatus according to the present technology described above may include a charge reset unit that resets charges accumulated in the charge holding unit.

This allows to share and use the charge reset unit that resets the charges accumulated in the charge holding unit.

In the imaging apparatus according to the present technology described above, the charge holding unit may hold charges accumulated in the photoelectric conversion elements disposed facing each other in the light incident direction in different the photoelectric conversion units.

This allows to reduce chances of misalignment of pixels of the respective photoelectric conversion units, because the photoelectric conversion elements disposed facing each other are stacked in the light incident direction.

In the imaging apparatus according to the present technology described above, each of the photoelectric conversion units may include a first photoelectric conversion unit and a second photoelectric conversion unit that are stacked along the light incident direction, the first photoelectric conversion unit may include the photoelectric conversion element using an organic material that receives and photoelectrically converts light in a specific wavelength region, and the second photoelectric conversion unit may include the photoelectric conversion element using an inorganic material that receives and photoelectrically converts light.

This allows to enhance efficiency of photoelectric conversion in the second photoelectric conversion unit, because attenuation of transmitted light in the first photoelectric conversion unit is small.

The imaging apparatus according to the present technology described above may include a charge discharging unit that discharges charges accumulated in the photoelectric conversion element in the second photoelectric conversion unit.

This allows to reset the charges accumulated in the photoelectric conversion element in the second photoelectric conversion unit.

In the imaging apparatus according to the present technology described above, each of the photoelectric conversion units may include a first photoelectric conversion unit and a second photoelectric conversion unit that are stacked along the light incident direction, the first photoelectric conversion unit may include the photoelectric conversion element that receives and photoelectrically converts visible light, and the second photoelectric conversion unit may include the photoelectric conversion element that receives and photoelectrically converts infrared light.

This allows the first photoelectric conversion unit to enhance efficiency of photoelectric conversion more than the second photoelectric conversion unit does.

The imaging apparatus according to the present technology described above may include a distance signal processing unit that generates, on the basis of a charge photoelectrically converted by the photoelectric conversion element in the second photoelectric conversion unit, a range image indicating a distance to a target object.

This allows to acquire an image based on visible light and the range image indicating the distance to the target object.

In the imaging apparatus according to the present technology described above, the photoelectric conversion element in the second photoelectric conversion unit may have a light receiving area larger than a light receiving area of the photoelectric conversion element in the first photoelectric conversion unit.

This allows to increase a charge amount in the second photoelectric conversion unit, which is farther from the target object than the first photoelectric conversion unit is, and having lower photoelectric efficiency than the first photoelectric conversion unit does.

The imaging apparatus according to the present technology described above may include a drive control unit that transfers, to the charge holding unit at different timings, charges accumulated in the photoelectric conversion elements in different the photoelectric conversion units.

This allows to sequentially acquire charges generated by photoelectric conversion by the photoelectric conversion elements in the different stacked photoelectric conversion units.

An information processing apparatus according to the present technology includes an imaging apparatus that captures an image, and an information processing unit that executes predetermined processing on the basis of the image captured by the imaging apparatus, in which the imaging apparatus includes a plurality of photoelectric conversion units, each including a photoelectric conversion element that performs photoelectric conversion with light in a different wavelength region, the photoelectric conversion units being stacked in a light incident direction, and a charge holding unit that holds charges accumulated in the photoelectric conversion element in different the photoelectric conversion units.

This allows to share and use a photoelectric holding unit for the different stacked photoelectric conversion units.

In the information processing apparatus according to the present technology described above, each of the photoelectric conversion units may include a first photoelectric conversion unit and a second photoelectric conversion unit that are stacked along the light incident direction, the first photoelectric conversion unit may include the photoelectric conversion element that receives and photoelectrically converts visible light, and the second photoelectric conversion unit may include the photoelectric conversion element that receives and photoelectrically converts infrared light.

This allows to perform processing on the basis of an image based on the visible light and an image indicating a distance to the target object based on the infrared light.

In the information processing apparatus according to the present technology described above, the imaging apparatus may include a visible signal processing unit that generates a visible image on the basis of a charge photoelectrically converted by the photoelectric conversion element in the first photoelectric conversion unit, and a distance signal processing unit that generates, on the basis of a charge photoelectrically converted by the photoelectric conversion element in the second photoelectric conversion unit, a range image indicating a distance to a target object, and the information processing unit may decide, on the basis of the visible image, whether or not the range image is captured.

This allows to switch whether or not to capture the range image, depending on the target object included in the visible image.

In the information processing apparatus according to the present technology described above, the imaging apparatus may include a visible signal processing unit that generates a visible image on the basis of a charge photoelectrically converted by the photoelectric conversion element in the first photoelectric conversion unit, and a distance signal processing unit that generates, on the basis of a charge photoelectrically converted by the photoelectric conversion element in the second photoelectric conversion unit, a range image indicating a distance to a target object, and the information processing unit may decide, on the basis of the range image, whether or not the visible image is captured.

This allows to switch whether or not to capture the range image, depending on the target object included in the range image.

### BRIEF DESCRIPTION OF DRAWINGS

FIG. 1 is a block diagram for describing a configuration example of an imaging apparatus according to the present technology.

FIG. 2 is a block diagram illustrating an internal circuit configuration example of an imaging unit.

FIG. 3 is a schematic diagram illustrating disposition of pixels.

FIG. 4 is a cross-sectional view for describing a schematic structure of a pixel array unit.

FIG. 5 is a diagram illustrating an equivalent circuit of a pixel block in the pixel array unit.

FIG. 6 is a diagram describing a timing chart of operation in the pixel block.

FIG. 7 is a diagram describing a timing chart of operations of a plurality of photodiodes in a second photoelectric conversion unit.

FIG. 8 is a schematic diagram illustrating a configuration example of a pixel array unit as a second embodiment.

FIG. 9 is a diagram describing a timing chart of operations of a plurality of photodiodes in a second photoelectric conversion unit as the second embodiment.

FIG. 10 is a block diagram for describing a configuration example of an information processing apparatus.

FIG. 11 is a flowchart illustrating a flow of information processing in a first example.

FIG. 12 is a flowchart illustrating a flow of information processing in a second example.

### MODE FOR CARRYING OUT THE INVENTION

Hereinafter, embodiments according to the present technology will be described in the following order with reference to the accompanying drawings.
<1. First Embodiment>
[1-1. Configuration of imaging apparatus]
[1-2. Circuit configuration of sensor unit]
[1-3. Structure of pixel array unit]
[1-4. Circuit configuration of pixel array unit]
<2. Second Embodiment>
<3. Modifications>
<4. Application to information processing apparatus>
[4-1. Configuration of information processing apparatus]
[4-2. First example]
[4-3. Second example]
[4-4. Modifications]
<5. Conclusion of embodiments>
<6. Present technology>

### 1. First Embodiment

[1-1. Configuration of Imaging Apparatus]

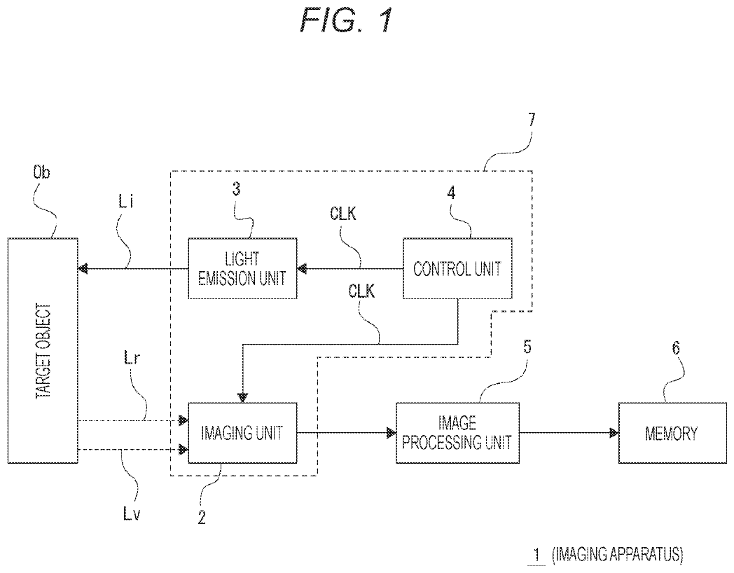

FIG. 1 is a block diagram for describing a configuration example of an imaging apparatus 1 as a first embodiment according to the present technology.

As illustrated in FIG. 1, an imaging apparatus 1 includes an imaging unit 2, a light emission unit 3, a control unit 4, an image processing unit 5, and a memory 6. In the present example, the imaging unit 2, the light emission unit 3, and the control unit 4 are formed on the same substrate, and are configured as a sensing module 7.

The imaging apparatus 1 is an apparatus that captures an image based on visible light and an image based on infrared light. Hereinafter, an image based on visible light is referred to as a visible image, and an image based on infrared light is referred to as a range image.

The light emission unit 3 includes one or a plurality of light emitting elements as a light source, and emits irradiation light Li to a target object Ob. Specifically, in the present example, the light emission unit 3 emits infrared light having a wavelength in a range of 780 nm to 1000 nm as the irradiation light Li.

The control unit 4 controls light emission operation of the irradiation light Li by the light emission unit 3. Specifically, in the present example, the light emission unit 3 repeatedly emits pulsed light as the irradiation light Li at a predetermined cycle.

In the imaging unit 2, a plurality of photoelectric conversion units is stacked as will be described in detail later. In the present example, two photoelectric conversion units are stacked in the imaging unit 2. The imaging unit 2 receives, with one photoelectric conversion unit, reflected light Lr emitted from the light emission unit 3 and reflected by the target object Ob, and, on the basis of a phase difference between the reflected light Lr and the irradiation light Li, outputs distance information by an indirect Time of Flight (ToF) method as a range image. Note that the indirect ToF method is a raging method for calculating a distance to the target object Ob on the basis of the phase difference between the irradiation light Li to the target object Ob and the reflected light Lr obtained by the irradiation light Li being reflected by the target object Ob. Therefore, in the range image, it can be said that information indicating the distance to the target object Ob is indicated in each pixel.

Furthermore, the imaging unit 2 receives visible light Lv reflected by the target object Ob with another photoelectric conversion unit, and outputs a visible image based on the received visible light.

The image processing unit 5 receives the visible image obtained in the imaging unit 2 and the range image, performs predetermined signal processing such as compression and encoding on the images, for example, and outputs the images to the memory 6.

The memory 6 is a storage apparatus such as a flash memory, a solid state drive (SSD), or a hard disk drive (HDD), for example, and stores the visible image and range image processed by the image processing unit 5.

[1-2. Circuit Configuration of Sensor Unit]

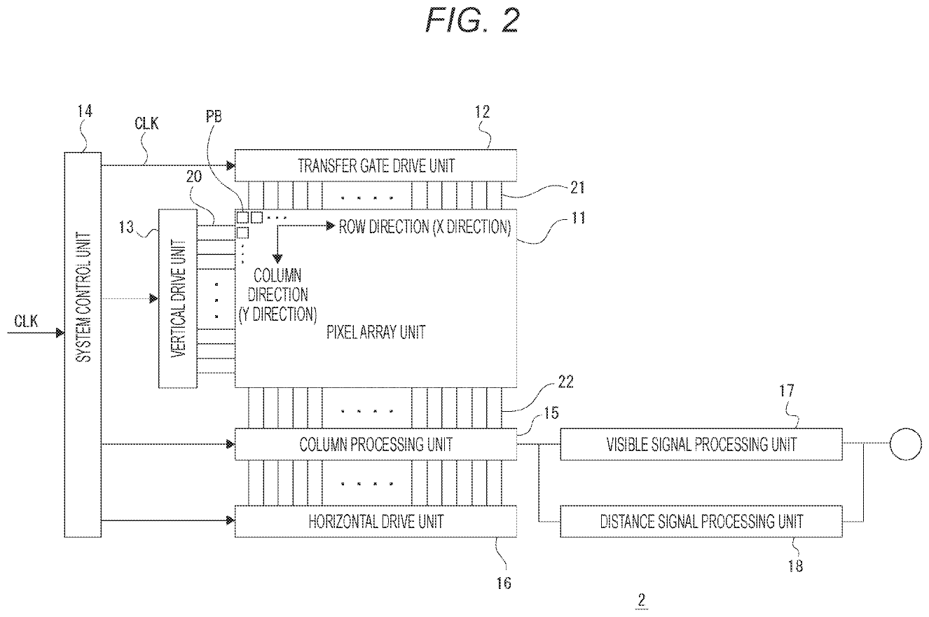

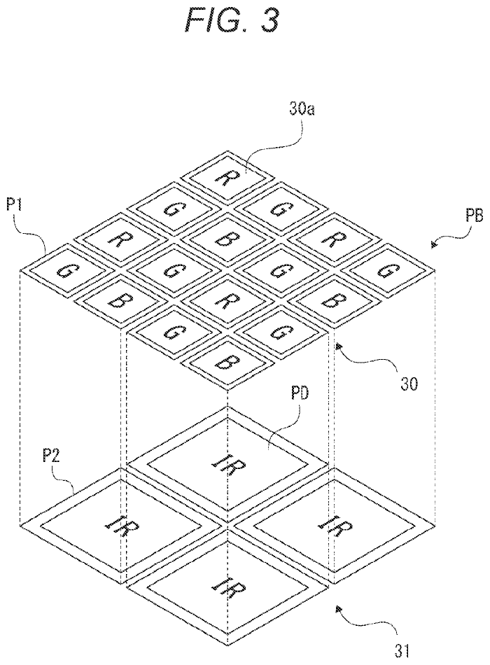

FIG. 2 is a block diagram illustrating an internal circuit configuration example of the imaging unit 2. FIG. 3 is a schematic diagram illustrating disposition of pixels.

As illustrated in FIG. 2, the imaging unit 2 includes a pixel array unit 11, a transfer gate drive unit 12, a vertical drive unit 13, a system control unit 14, a column processing unit 15, a horizontal drive unit 16, a visible signal processing unit 17, and a distance signal processing unit 18.

As illustrated in FIG. 3, in the pixel array unit 11, a first photoelectric conversion unit 30 and a second photoelectric conversion unit 31, each including a photoelectric conversion element that performs photoelectric conversion with light in a different wavelength region, are stacked in a light incident direction. In the first photoelectric conversion unit 30 and the second photoelectric conversion unit 31, a plurality of pixels is two-dimensionally arranged in a matrix in a row direction and in a column direction. The first photoelectric conversion unit 30 is disposed closer to the target object Ob than the second photoelectric conversion unit 31 is, that is, disposed on a light receiving surface side.

Here, the row direction refers to an arrangement direction of the pixels in a horizontal direction, and the column direction refers to an arrangement direction of the pixels in a vertical direction. In FIG. 2, the row direction is a lateral direction, and the column direction is a longitudinal direction.

In the first photoelectric conversion unit 30, first pixels P1 (organic photoelectric conversion elements 30a) are two-dimensionally arranged in a matrix in the row direction and in the column direction. The first pixel P1 includes an organic photoelectric conversion element 30a using an organic material that receives and photoelectrically converts light of a specific color (light in a specific wavelength region). In the present example, the first pixel P1 includes an organic photoelectric conversion element 30a that receives and photoelectrically converts visible light of red (R), green (G), or blue (B). Note that, in FIG. 3, an organic photoelectric conversion element 30a that receives and photoelectrically converts visible red (R) light is denoted as “R”, an organic photoelectric conversion element 30a that receives and photoelectrically converts visible green (G) light is denoted as “G”, and an organic photoelectric conversion element 30a that receives and photoelectrically converts visible blue (B) light is denoted as “B”.

In the first photoelectric conversion unit 30, organic photoelectric conversion elements 30a (first pixels P1), each receiving and photoelectrically converting visible light of red (R), green (G), or blue (B), are disposed in a Bayer pattern, for example. Note that, in the first photoelectric conversion unit 30, organic photoelectric conversion elements 30a that receive and photoelectrically convert visible light of red (R), green (G), or blue (B) may be disposed in another arrangement. Furthermore, in the first photoelectric conversion unit 30, organic photoelectric conversion elements 30a, which receive and photoelectrically convert visible light of red (R), green (G), and blue (B) not separately, may be disposed. Furthermore, in the first photoelectric conversion unit 30, the first pixels P1 including inorganic photoelectric conversion elements using an inorganic material such as silicon may be arranged. In this case, for example, it is only required to dispose, in the pixel array unit 11, color filters, each transmitting only visible light of red (R), green (G), or blue (B), closer to the target object Ob than the first photoelectric conversion unit 30 is.

In the second photoelectric conversion unit 31, a plurality of second pixels P2 is two-dimensionally arranged in a matrix in the row direction and in the column direction. The second pixel P2 includes a photodiode PD as an inorganic photoelectric conversion element using an inorganic material that receives and photoelectrically converts infrared light. Note that, in FIG. 3, a photodiode PD that receives and photoelectrically converts infrared light is also referred to as “IR”.

A light receiving area of a photodiode PD is larger than a light receiving area of an organic photoelectric conversion element 30a. In the present example, the light receiving area of the photodiode PD has an area corresponds to four times the light receiving area of the organic photoelectric conversion element 30a. Therefore, a second pixel P2 has an area corresponding to four first pixels P1, that is, four times an area of a first pixel P1.

Then, in the pixel array unit 11, four first pixels P1 (organic photoelectric conversion elements 30a) and one second pixel P2 (photodiode PD) are disposed to face each other in the light incident direction. Therefore, it can also be said that, in the pixel array unit 11, pixel blocks PB, each including a set of one second pixel P2 and four first pixels P1 disposed to face the one second pixel P2, are disposed two-dimensionally in the row direction and in the column direction.

In the pixel array unit 11, a row drive line 20 is wired along the row direction for each row of the pixel block PB. Furthermore, in the pixel array unit 11, a gate drive line 21 is wired along the column direction for each column of the pixel block PB. Furthermore, in the pixel array unit 11, a vertical signal line 22 is wired along the column direction for each column of the pixel block PB.

For example, the row drive line 20 sends a drive signal for performing driving when a signal charge is read from the first pixel P1 or the second pixel P2. Note that, although the row drive line 20 is illustrated as one wiring in FIG. 2, the wiring is not limited to one. One end of the row drive line 20 is connected to an output end corresponding to each row of the vertical drive unit 13.

The system control unit 14 includes, for example, a timing generator that generates various timing signals, and performs drive control of the transfer gate drive unit 12, the vertical drive unit 13, the column processing unit 15, the horizontal drive unit 16, and the like on the basis of various timing signals generated by the timing generator or the like.

The transfer gate drive unit 12 drives the organic photoelectric conversion elements 30a and a transfer gate element (transfer transistor TG), which will be described later, through the gate drive line 21 on the basis of control by the system control unit 14. Therefore, the system control unit 14 supplies the transfer gate drive unit 12 with a clock CLK input from the control unit 4 illustrated in FIG. 1, and the transfer gate drive unit 12 drives the organic photoelectric conversion elements 30a and the transfer gate element on the basis of the clock CLK.

The vertical drive unit 13 includes a shift register, an address decoder, and the like, and drives all the first pixels P1 and second pixels P2 of the pixel array unit 11 at the same time, row by row, or the like. That is, the vertical drive unit 13 constitutes a drive control unit that controls operation of the first pixels P1 and second pixels P2 of the pixel array unit 11 together with the system control unit 14 that controls the vertical drive unit 13.

A detection signal output (read) from a first pixel P1 or second pixel P2 according to drive control by the vertical drive unit 13, specifically, a signal corresponding to signal charges accumulated in the floating diffusion provided for each pixel block PB, is input to the column processing unit 15 through a corresponding vertical signal line 22. The column processing unit 15 performs predetermined signal processing on the detection signal read from the first pixel P1 or second pixel P2 through the vertical signal line 22, and temporarily holds the detection signal subjected to the signal processing. Specifically, the column processing unit 15 performs noise removal processing, analog to digital (A/D) conversion processing, or the like as signal processing.

The horizontal drive unit 16 includes a shift register, an address decoder, and the like, and sequentially selects a unit circuit corresponding to a column of the pixel block PB of the column processing unit 15. Selective scanning by the horizontal drive unit 16 sequentially outputs detection signals subjected, in the column processing unit 15, to the signal processing for each unit circuit.

The visible signal processing unit 17 includes at least an arithmetic processing function, and performs signal processing, such as correction processing between color channels, white balance correction, aberration correction, or shading correction on the detection signal read from the first pixel P1 and output from the column processing unit 15 to generate a visible image.

The distance signal processing unit 18 includes at least an arithmetic processing function, and performs various kinds of signal processing, such as processing of calculating distance corresponding to an indirect ToF method, on the detection signal read from the second pixel P2 and output from the column processing unit 15 to calculate distance information (generate a range image). Note that a known technique can be used as a technique of calculating distance information with the indirect ToF method on the basis of the detection signal, and therefore, description thereof will be omitted here.

[1-3. Structure of Pixel Array Unit]

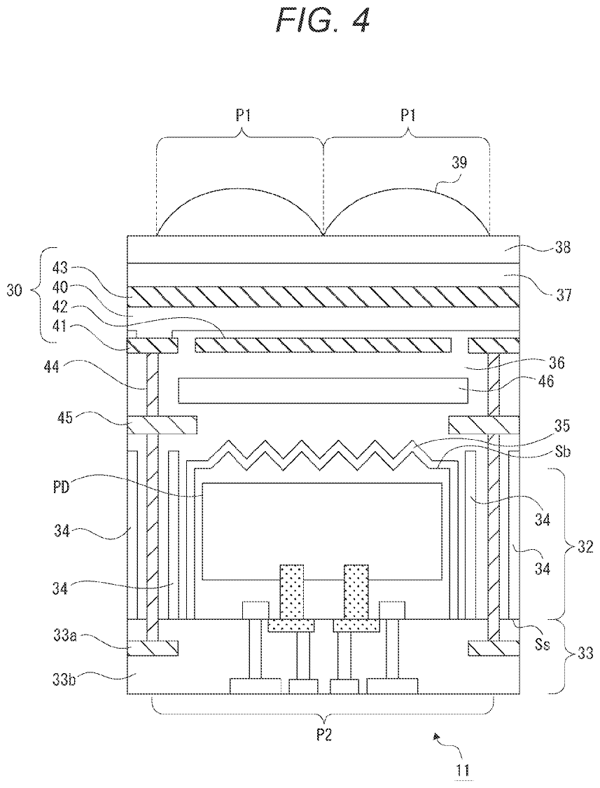

FIG. 4 is a cross-sectional view for describing a schematic structure of the pixel array unit 11.

As illustrated in FIG. 4, the pixel array unit 11 includes a semiconductor substrate 32 and a wiring layer 33 formed on a side close to a front surface Ss of the semiconductor substrate 32.

The semiconductor substrate 32 includes, for example, silicon (Si), and is formed with a thickness of, for example, about 1 μm to 6 μm. In the semiconductor substrate 32, a photodiode PD as an inorganic photoelectric conversion element is formed in a region of a second pixel P2 of the second photoelectric conversion unit 31. Adjacent photodiodes PD are electrically separated by an inter-pixel separation unit 34.

The wiring layer 33 is formed on the side close to the front surface Ss of the semiconductor substrate 32, and includes a plurality of layers of wirings 33a stacked with an interlayer insulating film 33b interposed therebetween. Pixel transistors to be described later are driven via the wirings 33a formed in the wiring layer 33.

On a back surface Sb of the semiconductor substrate 32, a fixed charge film 35 having a fixed charge is formed so as to surround the photodiode PD.

As the fixed charge film 35, a high refractive index material film having a negative charge or a high dielectric film can be used. As a specific material, for example, an oxide or nitride containing at least any one of elements, hafnium (Hf), aluminum (Al), zirconium (Zr), tantalum (Ta), or titanium (Ti), can be applied. Examples of a film forming method include a chemical vapor deposition (CVD) method, a sputtering method, an atomic layer deposition (ALD) method, and the like. Note that, if the ALD method is used, a silicon oxide (SiO₂) film that reduces an interface state can be formed to have a film thickness of about 1 nm at the same time as a film formation.

Note that silicon or nitrogen (N) may be added to a material of the fixed charge film 35 within a range where an insulating property thereof is not impaired. Concentration thereof is appropriately decided within a range where an insulating property of the film is not impaired. Thus, addition of silicon or nitrogen (N) allows an enhancement in heat resistance of the film or an improvement in ability to prevent ion implantation during a process.

An insulation layer 36 is formed around the fixed charge film 35. On the insulation layer 36, the first photoelectric conversion unit 30, a sealing film 37, a planarization film 38, and a microlens (on-chip lens) 39 are stacked in this order.

The first photoelectric conversion unit 30 (organic photoelectric conversion element 30a) includes a photoelectric conversion layer 40, a first electrode 41, a charge accumulation electrode 42, and a second electrode 43. The first electrode 41 and the charge accumulation electrode 42 are disposed so as to be separated in the insulation layer 36, and facing the photoelectric conversion layer 40. The second electrode 43 is disposed on the photoelectric conversion layer 40. One organic photoelectric conversion element 30a is formed in a region of each first pixel P1 of the first photoelectric conversion unit 30.

The first electrode 41, the charge accumulation electrode 42, and the second electrode 43 are transparent electrodes including ITO, IZO, or the like, for example. The first electrode 41 is connected to the photoelectric conversion layer 40 and is connected to a wiring 44 penetrating to the wiring 33a of the wiring layer 33.

Note that, although the pixel transistors (the transfer transistor TG, a reset transistor RST, an overflow (OF) gate transistor OFG, an amplification transistor AMP, and a selection transistor SEL) and a floating diffusion FD are also formed for the first pixels P1 and second pixel P2, illustration of the pixel transistors and the floating diffusion FD is omitted in FIG. 4. Here, conductors functioning as electrodes (each of the gate, drain, and source electrodes) of the pixel transistors and the floating diffusion FD are formed in the wiring layer 33, near the front surface Ss of the semiconductor substrate 32.

The insulation layer 36 is preferably formed with a material having a refractive index different from a refractive index of the fixed charge film 35, and for example, silicon oxide, silicon nitride, silicon oxynitride, resin, or the like can be used as the material. Furthermore, a material having a characteristic of not having a positive fixed charge or having a small positive fixed charge can be used for the insulation layer 36.

As the sealing film 37, an insulator containing aluminum (Al) or titanium (Ti) can be used.

The planarization film 38 is formed on the sealing film 37, by which a surface of a side close to the back surface Sb of the semiconductor substrate 32 is planarized. As a material of the planarization film 38, for example, an organic material such as resin can be used.

For each first pixel P1, the microlens 39 is formed on the planarization film 38. In the microlens 39, incident light is condensed, and the condensed light is efficiently incident on the organic photoelectric conversion elements 30a and the photodiode PD.

Furthermore, an inter-pixel light shielding unit 45 and a filter unit 46 are provided in the insulation layer 36.

On the side close to the back surface Sb of the semiconductor substrate 32, the inter-pixel light shielding unit 45 is formed in a lattice pattern so as to open the photodiode PD of each of the second pixels P2. That is, the inter-pixel light shielding unit 45 is formed at a position corresponding to the inter-pixel separation unit 34.

A material included in the inter-pixel light shielding unit 45 is only required to be a material capable of shielding light, and, for example, tungsten (W), aluminum (Al), or copper (Cu) can be used.

Between adjacent second pixels P2, the inter-pixel light shielding unit 45 prevents light to be incident only on one second pixel P2 from leaking into another second pixel P2.

The filter unit 46 is formed with a wavelength filter that transmits light in a predetermined wavelength region. Examples of the wavelength filter here include a wavelength filter that blocks visible light and transmits infrared light.

In the imaging apparatus 1 including the pixel array unit 11 as described above, light is emitted from the side close to the back surface Sb of the semiconductor substrate 32, and light that is in a predetermined wavelength region and is transmitted through the microlens 39 is photoelectrically converted by the organic photoelectric conversion elements 30a of the first photoelectric conversion unit 30, by which signal charges are generated. Then, the signal charges obtained by the photoelectric conversion are output through the pixel transistors formed on the side close to the front surface Ss of the semiconductor substrate 32, and via the vertical signal line 22 formed as a predetermined wiring 33a in the wiring layer 33.

Furthermore, in the imaging apparatus 1 including the pixel array unit 11, light is emitted from the side close to the back surface Sb of the semiconductor substrate 32, and infrared light transmitted through the first photoelectric conversion unit 30 and the filter unit 46 is photoelectrically converted by the photodiodes PD of the second photoelectric conversion unit 31, by which signal charges are generated. Then, the signal charges obtained by the photoelectric conversion are output through the pixel transistors formed on the side close to the front surface Ss of the semiconductor substrate 32, and via the vertical signal line 22 formed as a predetermined wiring 33a in the wiring layer 33.

[1-4. Circuit Configuration of Pixel Array Unit]

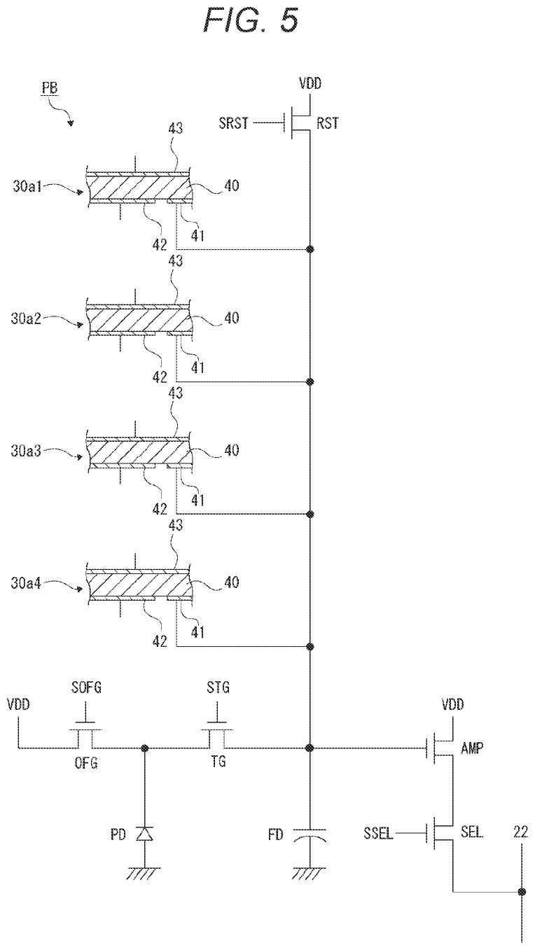

FIG. 5 is a diagram illustrating an equivalent circuit of a pixel block PB in the pixel array unit 11.

As illustrated in FIG. 5, the pixel block PB includes four organic photoelectric conversion elements (first pixels P1) and one photodiode PD (second pixel P2).

Here, in a case where the four organic photoelectric conversion elements 30a in the pixel block PB are distinguished, as illustrated in FIG. 5, the organic photoelectric conversion elements 30a are referred to as organic photoelectric conversion elements 30a2, 30a3, and 30a4.

Furthermore, the pixel block PB includes one reset transistor RST, one floating diffusion FD, one transfer transistor TG, one OF gate transistor OFG, one amplification transistor AMP, and one selection transistor SEL.

Each of the reset transistor RST, the transfer transistor TG, the OF gate transistor OFG, the amplification transistor AMP, and the selection transistor SEL includes, for example, an n-type MOS transistor.

A drain of the reset transistor RST is connected to a reference potential VDD (constant-current source), and a reset signal SRST is input to a gate of the reset transistor RST. Furthermore, the first electrodes 41 of the respective organic photoelectric conversion elements 30a1, 30a2, 30a3, and 30a4, a source of the transfer transistor TG, and the floating diffusion FD are connected to a source of the reset transistor RST.

When the reset signal SRST supplied to the gate thereof is turned on, the reset transistor RST enters a conductive state and resets a potential of the floating diffusion FD to the reference potential VDD.

Note that the reset signal SRST is supplied from the vertical drive unit 13, for example.

In the organic photoelectric conversion elements 30a, by the vertical drive unit 13, a positive potential is applied to the first electrode 41, and a negative potential is applied to the second electrode 43. In the organic photoelectric conversion elements 30a, photoelectric conversion occurs in the photoelectric conversion layer 40 by incident light. Holes generated by the photoelectric conversion are sent from the second electrode 43 to outside. Meanwhile, because a potential of the first electrode 41 is higher than a potential of the second electrode 43, electrons generated by the photoelectric conversion are attracted to the charge accumulation electrode 42 and stop in a region of the photoelectric conversion layer 40 facing the charge accumulation electrode 42. That is, signal charges are accumulated in the photoelectric conversion layer 40. At this time, the electrons generated inside the photoelectric conversion layer 40 do not move toward the first electrode 41. As a time of the photoelectric conversion elapses, a value of the potential in the region of the photoelectric conversion layer 40 facing the charge accumulation electrode 42 becomes more negative.

Thereafter, by the vertical drive unit 13, a predetermined potential is applied to the first electrode 41, and a potential lower than the potential of the first electrode 41 is applied to the charge accumulation electrode 42. As a result, electrons that have stopped in the region of the photoelectric conversion layer 40 facing the charge accumulation electrode 42 are transferred, as signal charges, to the floating diffusion FD via the first electrode 41. At this time, the floating diffusion FD functions as a charge holding unit that temporarily holds the signal charges transferred from the organic photoelectric conversion elements 30a.

The OF gate transistor OFG is provided as a charge discharging unit to discharge the charges accumulated in the photodiode PD, and enters a conductive state when an OF gate signal SOFG supplied to the gate is turned on. When the OF gate transistor OFG enters the conductive state, the photodiode PD is clamped at a predetermined reference potential VDD, and the accumulated charges are reset.

Note that the OF gate signal SOFG is supplied from the vertical drive unit 13, for example.

When a transfer drive signal STG supplied to a gate of the transfer transistor TG is turned on, the transfer transistor TG enters a conductive state, and transfers the signal charges accumulated in the photodiode PD to the floating diffusion FD. At this time, the floating diffusion FD functions as a charge holding unit that temporarily holds the signal charges transferred from the photodiode PD.

The amplification transistor AMP has a source connected to the vertical signal line 22 via the selection transistor SEL, and a drain connected to a reference potential VDD (constant-current source) to constitute a source follower circuit.

The selection transistor SEL is connected between the source of the amplification transistor AMP and the vertical signal line 22 and, when a selection signal SSEL supplied to a gate of the selection transistor SEL is turned on, enters a conductive state and outputs the signal charges held in the floating diffusion FD to the vertical signal line 22 via the amplification transistor AMP.

Note that the selection signal SSEL is supplied from the vertical drive unit 13 via the row drive line 20.

Thus, in the pixel array unit 11, one floating diffusion FD, one selection transistor SEL, and one amplification transistor AMP are provided for each pixel block PB. That is, the floating diffusion FD, the selection transistor SEL, and the amplification transistor AMP are shared by the first photoelectric conversion unit 30 and the second photoelectric conversion unit 31.

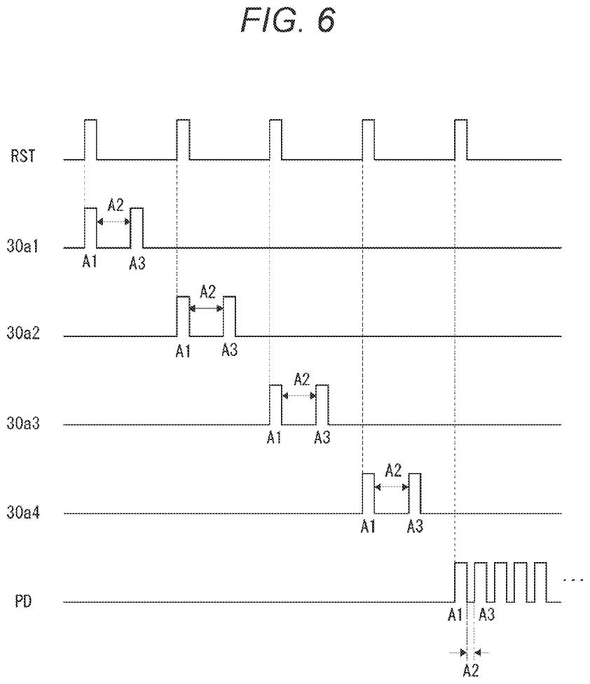

FIG. 6 is a diagram describing a timing chart of operation in the pixel block PB.

Next, operations in the pixel block PB will be briefly described.

In the pixel block PB, operations including a reset operation A1, a light-receiving operation A2, and a transfer operation A3 are performed on the organic photoelectric conversion elements 30a1, 30a2, 30a3, and and the photodiode PD in this order. That is, charges are transferred to the organic photoelectric conversion elements 30a1, 30a2, 30a3, and 30a4, and the photodiode PD at different timings. First, in the pixel block PB, the reset operation A1 is performed on the organic photoelectric conversion element 30a1. For example, the reset transistor RST is turned on (enters the conductive state), a predetermined potential is applied to the first electrode 41, and a potential lower than the potential of the first electrode 41 is applied to the charge accumulation electrode 42. As a result, the accumulated charges in the organic photoelectric conversion element 30a1 and in the floating diffusion FD are reset.

After resetting the accumulated charges, the light-receiving operation A2 of the organic photoelectric conversion element 30a1 is started. Here, a positive potential is applied to the first electrode 41, and a negative potential is applied to the second electrode 43.

Thereafter, in the transfer operation A3, a predetermined potential is applied to the first electrode 41, and a potential lower than the potential of the first electrode 41 is applied to the charge accumulation electrode 42. As a result, the signal charges (accumulated charges) accumulated in the organic photoelectric conversion element 30a1 are transferred to the floating diffusion FD.

Thereafter, all the pixel blocks PB of the pixel array unit 11 are selected line by line. In the selected pixel block PB, the selection transistor SEL is turned on. As a result, the signal charges accumulated in the floating diffusion FD are output to the column processing unit 15 via the vertical signal line 22.

Thus, when the reset operation A1, light-receiving operation A2, and transfer operation A3 of the organic photoelectric conversion element 30a1 are completed, the reset operation A1, light-receiving operation A2, and transfer operation A3 of the organic photoelectric conversion element 30a2 are started. Furthermore, when the reset operation A1, light-receiving operation A2, and transfer operation A3 of the organic photoelectric conversion element 30a2 are completed, the reset operation A1, light-receiving operation A2, and transfer operation A3 of the organic photoelectric conversion element 30a3 are started. Furthermore, when the reset operation A1, light-receiving operation A2, and transfer operation A3 of the organic photoelectric conversion element 30a3 are completed, the reset operation A1, light-receiving operation A2, and transfer operation A3 of the organic photoelectric conversion element 30a4 are started. Note that the reset operation A1, light-receiving operation A2, and transfer operation A3 of the organic photoelectric conversion elements 30a2, 30a3, and 30a4 are similar to the reset operation A1, light-receiving operation A2, and transfer operation A3 of the organic photoelectric conversion element 30a, and thus description thereof is omitted.

When the reset operation A1, light-receiving operation A2, and transfer operation A3 of the organic photoelectric conversion element 30a4 are completed, the reset operation A1, light-receiving operation A2, and transfer operation A3 of the photodiode PD are started. When the reset operation A1 of the photodiode PD is started, the OF gate transistor OFG, the reset transistor RST, and the transfer transistor TG are turned on (enter the conductive state). As a result, the accumulated charges in the photodiode PD and in the floating diffusion FD are reset.

Then, in the light-receiving operation A2 and the transfer operation A3, operation of turning on and off the transfer transistor TG is repeated a predetermined number of times (in the present example, about several thousand times to a few tens of thousands of times). Here, electric charges are accumulated in the photodiode PD while the transfer transistor TG is off, and the electric charges are transferred from the photodiode PD to the floating diffusion FD while the transfer transistor TG is on. Thereafter, the respective second pixels P2 of the pixel array unit 11 are selected line by line. In a selected second pixel P2, the selection transistor SEL is turned on. As a result, the charges accumulated in the floating diffusion FD are output to the column processing unit 15 via the vertical signal line 22.

This completes one operation, and a next operation is executed.

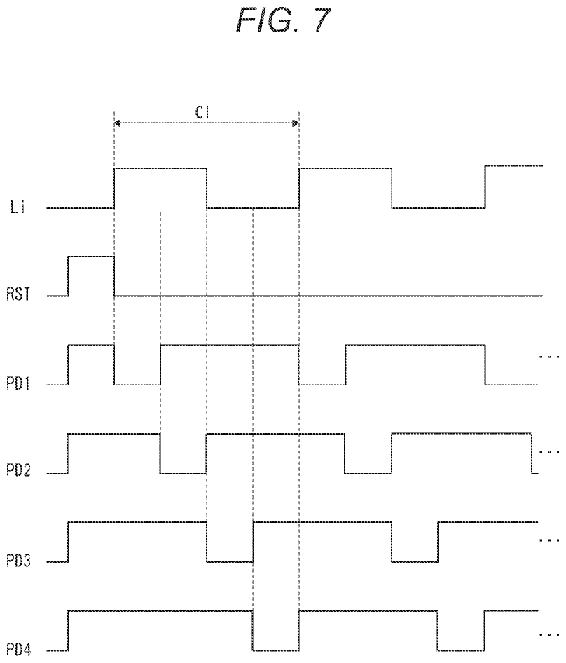

FIG. 7 is a diagram describing a timing chart of operations of a plurality of photodiodes PD in the second photoelectric conversion unit 31.

As described above, distance information by the indirect ToF method is output on the basis of a phase difference between reflected light Lr and irradiation light Li in infrared light received by the photodiode PD.

In this case, two rows×two columns=four photodiodes PD are controlled to operate in different phases. Here, in a case where the four photodiodes PD adjacent in the row direction and in the column direction are distinguished, as illustrated in FIG. 7, the photodiodes PD are referred to as photodiodes PD1, PD2, PD3, and PD4.

The control unit 4 controls light emission operation of the irradiation light Li by the light emission unit 3. In a case of the indirect ToF method, light having intensity modulated so that the intensity changes at a predetermined cycle is used as the irradiation light Li. Specifically, in the present example, as illustrated in FIG. 7, pulsed light is repeatedly emitted as the irradiation light Li at a predetermined cycle. Hereinafter, such a light emission cycle of the pulsed light is referred to as a “light emission cycle Cl”.

Here, in the indirect ToF method, the light emission cycle Cl is relatively fast, for example, about a few dozen MHz to a few hundred MHz.

The system control unit 14 controls the vertical drive unit 13 on the basis of the clock CLK to perform the reset operation A1 of turning on the reset transistor RST connected to the photodiodes PD1, PD2, PD3, and PD4. Here, the system control unit 14 turns on the OF gate transistors OFG and transfer transistors TG connected to the respective photodiodes PD1, PD2, PD3, and PD4.

Thereafter, the system control unit 14 repeats a control cycle of causing the photodiode PD1 to perform the light-receiving operation A2 in a ¼ light emission cycle Cl and the transfer operation A3 in a ¾ light emission cycle Cl in synchronization with the light emission operation of the irradiation light Li.

Furthermore, delayed by the ¼ light emission cycle Cl after the photodiode PD1, the system control unit 14 repeats a control cycle of causing the photodiode PD2 to perform the light-receiving operation A2 in the ¼ light emission cycle Cl and the transfer operation A3 in the ¾ light emission cycle Cl.

Furthermore, delayed by a ½ light emission cycle Cl after the photodiode PD1, the system control unit 14 repeats a control cycle of causing the photodiode PD2 to perform the light-receiving operation A2 in the ¼ light emission cycle Cl and the transfer operation A3 in the ¾ light emission cycle Cl.

Furthermore, delayed by the ¾ light emission cycle Cl after the photodiode PD1, the system control unit 14 repeats a control cycle of causing the photodiode PD2 to perform the light-receiving operation A2 in the ¼ light emission cycle Cl and the transfer operation A3 in the ¾ light emission cycle Cl.

Thus, the light-receiving operation A2 and transfer operation A3 of the photodiodes PD1, PD2, PD3, and PD4 are differentiated from each other by 90 degrees. Then, the distance signal processing unit 18 calculates, on the basis of the signal charges (detection signals) obtained from the photodiodes PD1, PD2, PD3, and PD4, distance information (generates a range image) with the indirect ToF method using four phases. Note that a known technique can be used as a technique of calculating distance information with the indirect ToF method using the four phases, and therefore, description thereof will be omitted here.

### 2. Second Embodiment

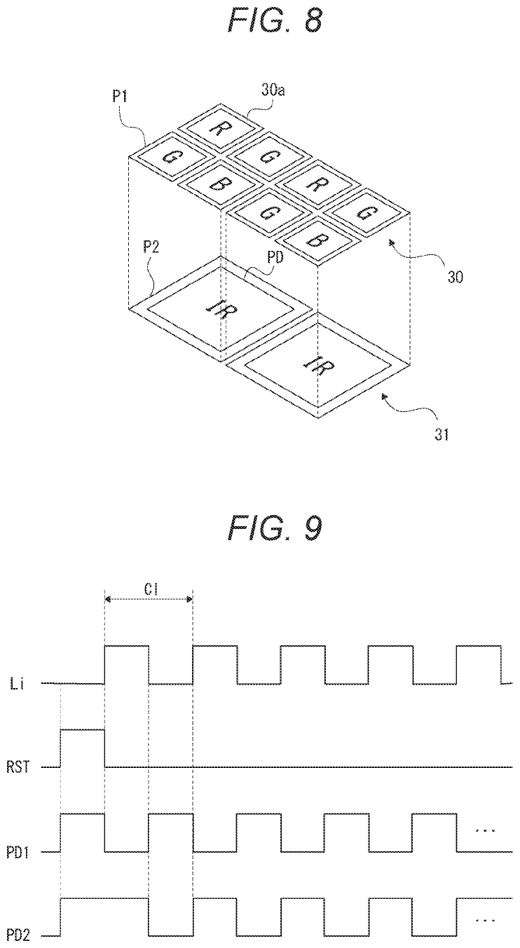

FIG. 8 is a schematic diagram illustrating a configuration example of a pixel array unit 11 as a second embodiment. FIG. 9 is a diagram describing a timing chart of operations of a plurality of photodiodes PD in a second photoelectric conversion unit 31 as the second embodiment.

Note that, in the following description, parts similar to parts already described will be denoted by the same reference signs, and therefore, description thereof will be omitted.

In the second embodiment, two rows×one column=two photodiodes PD (PD1, PD2) illustrated in FIG. 8 are operated in different phases.

A system control unit 14 controls a vertical drive unit 13 on the basis of a clock CLK to perform, in synchronization with the reset transistor RST turned on, a reset operation A1 of turning on the reset transistor RST connected to photodiodes PD1 and PD2. Here, the system control unit 14 turns on an OF gate transistor OFG and transfer transistor TG connected to the photodiodes PD1 and PD2.

The system control unit 14 repeats a control cycle of causing the photodiode PD1 to perform a light-receiving operation A2 in a ½ light emission cycle Cl and a transfer operation A3 in the ½ light emission cycle Cl in synchronization with a light emission operation of irradiation light Li.

Furthermore, delayed by the ½ light emission cycle Cl after the photodiode PD1, the system control unit 14 repeats a control cycle of causing the photodiode PD2 to perform the light-receiving operation A2 in the ½ light emission cycle Cl and the transfer operation A3 in the ½ light emission cycle Cl.

Thus, the light-receiving operation A2 and transfer operation A3 of the photodiodes PD1 and PD2 are differentiated from each other by 180 degrees. Then, on the basis of signal charges (detection signals) obtained from the photodiodes PD1 and PD2, a distance signal processing unit 18 calculates distance information (generates a range image) with the indirect ToF method using two phases. Note that a known technique can be used as a technique of calculating distance information with the indirect ToF method using the two phases, and therefore, description thereof will be omitted here.

### 3. Modifications

Note that the embodiments are not limited to the specific examples described above, and may be configured as various modifications.

In the first embodiment and the second embodiment, a first photoelectric conversion unit 30 includes first pixels P1, each of which includes an organic photoelectric conversion element 30a, and a second photoelectric conversion unit 31 includes second pixels P2, each of which includes a photodiode PD. However, the first photoelectric conversion unit 30 and the second photoelectric conversion unit 31 may have any configuration as long as each of the first photoelectric conversion unit and the second photoelectric conversion unit includes a photoelectric conversion element that photoelectrically converts light in a different wavelength region.

For example, the first pixel P1 may be a photodiode. In this case, there may be provided a transfer transistor for transferring, to a floating diffusion FD, signal charges generated by photoelectric conversion in the first pixel P1. The transfer transistor connected to the first pixel P1 is only required to be turned on when a transfer operation A3 is performed.

In the first embodiment and the second embodiment, in the first photoelectric conversion unit 30, the first pixels P1 having photoelectric conversion layers 40 that receive and photoelectrically convert visible light of red (R), green (G), and blue (B) disposed in a Bayer pattern. However, the first pixel P1 may be formed with stacked photoelectric conversion layers 40 that receive and photoelectrically convert visible light of red (R), green (G), or blue (B). That is, the first pixel P1 may be provided with three photoelectric conversion layers 40, each of which receives and photoelectrically converts visible light of red (R), green (G), or blue (B).

In the first embodiment and the second embodiment, an imaging apparatus 1 derives distance information with the indirect ToF method. However, the imaging apparatus 1 may derive distance information with a direct ToF method. Furthermore, timings of operations of the photodiode PD may be other than timings of operations of a photodiode PD described in the first embodiment and the second embodiment.

In the first embodiment and the second embodiment, a second pixel P2 has a light receiving area corresponding to light receiving areas of four first pixels P1. However, the light receiving area of the second pixel P2 may be the same as the light receiving area of the first pixel P1, may be larger than the light receiving area of the first pixel P1, or may be smaller than the light receiving area of the first pixel P1.

In the first embodiment and the second embodiment, each of pixel blocks PB includes one reset transistor RST, one floating diffusion FD, one transfer transistor TG, one OF gate transistor OFG, one amplification transistor AMP, and one selection transistor SEL. However, at least one floating diffusion FD is only required to be provided for each pixel block PB. Therefore, for example, the reset transistor RST may be provided not for each pixel block PB but for each organic photoelectric conversion element 30a and each photodiode PD.

In the first embodiment and the second embodiment, the imaging apparatus 1 continuously and alternately acquires visible images and range images. However, the imaging apparatus 1 may continuously acquire only either the visible images or the range images, or may acquire either the visible images or the range images at a predetermined timing while only the other type of images are continuously acquired. For example, the imaging apparatus 1 may continuously acquire only the visible images by continuously operating only the first photoelectric conversion unit 30. Furthermore, the imaging apparatus 1 may continuously acquire only the range images by continuously operating only the second photoelectric conversion unit 31.

### 4. Application to Information Processing Apparatus

### 4-1. Configuration of Information Processing Apparatus

The imaging apparatus 1 according to the above-described first embodiment, second embodiment, or modifications can be adapted to an information processing apparatus such as a digital still camera, a digital video camera, a mobile phone, or a personal computer, for example.

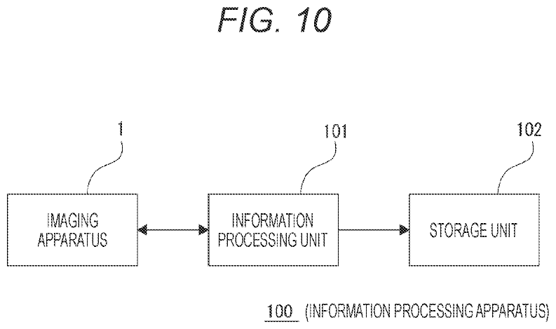

FIG. 10 is a block diagram for describing a configuration example of an information processing apparatus 100.

As illustrated in FIG. 10, the information processing apparatus 100 includes an imaging apparatus 1, an information processing unit 101, and a storage unit 102.

The information processing unit 101 includes a microcomputer including a central processing unit (CPU), a random access memory (RAM), and a read only memory (ROM). The information processing unit 101 appropriately controls the imaging apparatus 1 and the storage unit 102.

The storage unit 102 is a storage apparatus such as a flash memory, a solid state drive (SSD), or a hard disk drive (HDD), for example.

### 4-2. First Example

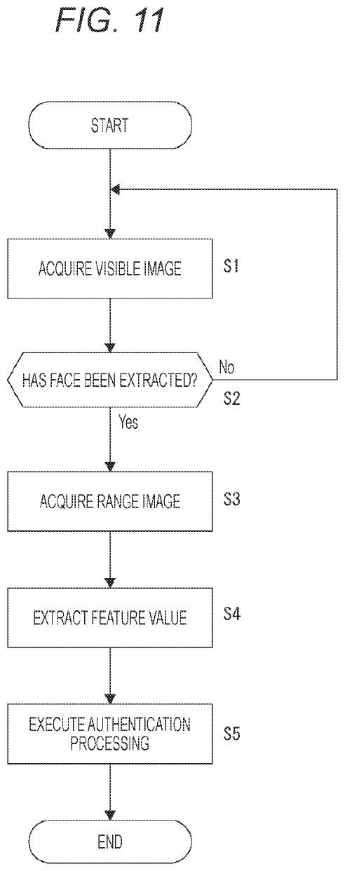

FIG. 11 is a flowchart illustrating a flow of information processing in a first example.

The information processing unit 101 executes facial authentication processing as the first example of the information processing. In the facial authentication processing as the first example, authentication information regarding a face to be authenticated is previously stored in the storage unit 102. Specifically, the information processing unit 101 extracts positions of characteristic points, such as a mouth, a nose, and eyes of the face, from a visible image obtained by the imaging apparatus 1 capturing an image of the face to be authenticated. Furthermore, the information processing unit 101 derives distances of the extracted characteristic points from a range image obtained by the imaging apparatus 1 capturing the image of the face to be authenticated. Then, the derived positions and distances of the characteristic points are stored in the storage unit 102 as authentication information.

Upon starting the facial authentication processing, in Step S1, the information processing unit 101 controls the imaging apparatus 1 to acquire the visible image. In Step S2, the information processing unit 101 executes extraction processing of extracting a human face from the acquired visible image, and determines whether or not a face has been extracted from the visible image.

In a case where it is not determined in Step S2 that a face has been extracted from the visible image, the processing returns to Step S1. Meanwhile, in a case where it is determined in Step S2 that a face has been extracted from the visible image, in Step S3, the information processing unit 101 controls the imaging apparatus 1 to acquire the range image. Thereafter, in Step S4, the information processing unit 101 derives, from the acquired visible image and range image, the characteristic points and distances of the characteristic points. In Step S5, the information processing unit 101 executes authentication processing of comparing the authentication information stored in the storage unit 102 with the characteristic points and distances of the characteristic points derived in Step S4. Note that a known technique can be used as the authentication processing, and therefore, description thereof will be omitted here.

As a result, the information processing apparatus 100 can execute highly accurate facial authentication processing by using the imaging apparatus 1. Furthermore, because the information processing apparatus 100 captures only visible images until a face is detected, processing loads can be reduced.

### 4-3. Second Example

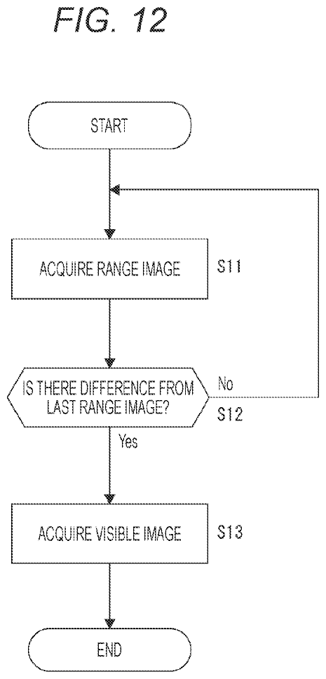

FIG. 12 is a flowchart illustrating a flow of information processing in a second example.

The information processing unit 101 executes monitoring processing as the second example of the information processing. Upon starting the monitoring processing, in Step S11, the information processing unit 101 controls the imaging apparatus 1 to acquire the range image, and stores the range image in the storage unit 102. Note that, regarding the range image, it is only required that at least a last captured range image be stored in the storage unit 102, and the range image already stored in the storage unit 102 may be deleted when a new range image is stored in the storage unit 102.

In Step S12, the information processing unit 101 compares the acquired range image with, for example, the last range image stored in the storage unit 102, and determines whether or not a preset difference has been detected. Here, for example, on the basis of distance information of respective corresponding pixels in the two range images, it is determined whether or not some object is newly captured.

In a case where it is not determined in Step S12 that there is a difference, the processing returns to Step S11. Meanwhile, in a case where it is determined in Step S12 that there is a difference, in Step S13, the information processing unit 101 controls the imaging apparatus 1 to acquire the visible image, and stores the visible image in the storage unit 102.

As a result, in the information processing apparatus 100, the visible image can be stored in the storage unit 102 over a timing at which some object is newly captured, and the visible image can be prevented from being stored in the storage unit 102 at a timing other than the timing at which some object is newly captured. Therefore, the information processing apparatus 100 can reduce capacity of data stored in the storage unit 102. Furthermore, because only a range image is stored in the storage unit 102 while some object is not newly captured, personal information to be stored can be reduced as compared with a case where the visible image is stored.

### 4-4. Modifications

Note that the embodiments are not limited to the specific examples described above, and may be configured as various modifications.

The facial authentication processing is executed in the first example, and the monitoring processing is executed in the second example. However, the information processing apparatus 100 may execute any processing as long as predetermined processing using a visible image and range image captured by the imaging apparatus 1 is performed.

### 5. Conclusion of Embodiments

As described above, an imaging apparatus 1 as an embodiment includes a plurality of photoelectric conversion units (a first photoelectric conversion unit 30, a second photoelectric conversion unit 31, for example), each including a photoelectric conversion element (an organic photoelectric conversion element 30a, a photodiode PD, for example) that performs photoelectric conversion with light in a different wavelength region, the photoelectric conversion units being stacked in a light incident direction, and a charge holding unit (a floating diffusion FD, for example) that holds charges accumulated in the photoelectric conversion element in the different photoelectric conversion units.

This allows the imaging apparatus 1 to share and use a photoelectric holding unit for the photoelectric conversion elements in the different stacked photoelectric conversion units.

Therefore, the imaging apparatus 1 does not need to be provided with a charge holding unit for each of the photoelectric conversion elements in the different stacked photoelectric conversion units, and therefore, a configuration of the imaging apparatus 1 can be simplified.

Furthermore, the imaging apparatus 1 as an embodiment may include a charge reset unit (a reset transistor RST) that resets charges accumulated in the charge holding unit.

This allows the imaging apparatus 1 to share and use the charge reset unit that resets the charges accumulated in the charge holding unit.

Therefore, the imaging apparatus 1 does not need to be provided with a charge reset unit for each of the photoelectric conversion elements in the different stacked photoelectric conversion units, and therefore, a configuration of the imaging apparatus 1 can be simplified.

Moreover, in the imaging apparatus 1 as an embodiment, the charge holding unit may hold charges accumulated in the photoelectric conversion elements disposed facing each other in the light incident direction in the different photoelectric conversion units.

This allows the imaging apparatus 1 to reduce chances of misalignment of pixels of the respective photoelectric conversion units, because the photoelectric conversion elements disposed facing each other in the light incident direction are stacked in the light incident direction.

Therefore, the imaging apparatus 1 does not need to perform position correction between the acquired visible image and the range image, and therefore, processing loads can be reduced by an amount that the processing is not performed.

Furthermore, because the imaging apparatus 1 does not need to be provided with a processing apparatus for performing position correction, a structure of the imaging apparatus 1 can be simplified.

Moreover, in the imaging apparatus 1 as an embodiment, each of the photoelectric conversion units may include a first photoelectric conversion unit and a second photoelectric conversion unit that are stacked along the light incident direction, the first photoelectric conversion unit may include the photoelectric conversion element (an organic photoelectric conversion element 30a, for example) using an organic material that receives and photoelectrically converts light in a specific wavelength region, and the second photoelectric conversion unit may include the photoelectric conversion element (a photodiode PD, for example) using an inorganic material that receives and photoelectrically converts light.

This allows the imaging apparatus 1 to enhance efficiency (sensitivity) of photoelectric conversion in the second photoelectric conversion unit, because attenuation of transmitted light in the first photoelectric conversion unit is small.

Therefore, the imaging apparatus 1 can acquire high-definition distance information (range image) in the photoelectric conversion element in the second photoelectric conversion unit.

Moreover, the imaging apparatus 1 as an embodiment may include a charge discharging unit (an OF gate transistor OFG, for example) that discharges charges accumulated in the photoelectric conversion element in the second photoelectric conversion unit.

This allows the imaging apparatus 1 to accurately reset the charges accumulated in the photoelectric conversion element in the second photoelectric conversion unit.

Therefore, the imaging apparatus 1 can acquire high-definition distance information (range image) in the photoelectric conversion element in the second photoelectric conversion unit.

Moreover, in the imaging apparatus 1 as an embodiment, each of the photoelectric conversion units may include a first photoelectric conversion unit and a second photoelectric conversion unit that are stacked along the light incident direction, the first photoelectric conversion unit may include the photoelectric conversion element that receives and photoelectrically converts visible light, and the second photoelectric conversion unit may include the photoelectric conversion element that receives and photoelectrically converts infrared light.

This allows, in the imaging apparatus 1, the first photoelectric conversion unit to enhance efficiency of photoelectric conversion more than the second photoelectric conversion unit does.

Therefore, the imaging apparatus 1 can acquire high-definition visible information in the photoelectric conversion element in the first photoelectric conversion unit.

Moreover, the imaging apparatus 1 as an embodiment may include a distance signal processing unit 18 that generates, on the basis of a charge photoelectrically converted by the photoelectric conversion element in the second photoelectric conversion unit, a range image indicating a distance to a target object.

This allows the imaging apparatus 1 to acquire a visible image based on visible light and the range image indicating the distance to the target object.

Therefore, with a simple configuration, the imaging apparatus 1 can acquire the visible image based on the visible light and the range image indicating the distance to the target object.

Moreover, in the imaging apparatus 1 as an embodiment, the photoelectric conversion element in the second photoelectric conversion unit may have a light receiving area larger than a light receiving area of the photoelectric conversion element in the first photoelectric conversion unit.

This allows the imaging apparatus 1 to increase a charge amount in the second photoelectric conversion unit, which is farther from the target object than the first photoelectric conversion unit is, and having lower photoelectric efficiency than the first photoelectric conversion unit does.

Therefore, the imaging apparatus 1 can acquire high-definition distance information in the photoelectric conversion element in the second photoelectric conversion unit.

Moreover, the imaging apparatus 1 as an embodiment may include a drive control unit that transfers, to the charge holding unit at different timings, charges accumulated in the photoelectric conversion elements in the different photoelectric conversion units.

This allows the imaging apparatus 1 to sequentially acquire charges generated by photoelectric conversion by the photoelectric conversion elements in the different stacked photoelectric conversion units.

Therefore, the imaging apparatus 1 does not need to be provided with a charge holding unit for each of the photoelectric conversion elements in the different stacked photoelectric conversion units, and therefore, a configuration of the imaging apparatus 1 can be simplified.

As described above, an information processing apparatus 100 as an embodiment includes an imaging apparatus 1 that captures an image, and an information processing unit 101 that executes predetermined processing on the basis of the image captured by the imaging apparatus, in which the imaging apparatus includes a plurality of photoelectric conversion units (a first photoelectric conversion unit 30, a second photoelectric conversion unit 31, for example), each including a photoelectric conversion element (an organic photoelectric conversion element 30a, a photodiode PD, for example) that performs photoelectric conversion with light in a different wavelength region, the photoelectric conversion units being stacked in a light incident direction, and a charge holding unit (a floating diffusion FD, for example) that holds charges accumulated in the photoelectric conversion element in the different photoelectric conversion units.

This allows the information processing apparatus 100 to share and use a photoelectric holding unit for the different stacked photoelectric conversion units.

Therefore, the information processing apparatus 100 does not need to be provided with a charge holding unit for each of the photoelectric conversion elements in the different stacked photoelectric conversion units, and therefore, a configuration of the imaging apparatus 1 can be simplified.

Furthermore, in the information processing apparatus 100 as an embodiment, each of the photoelectric conversion units may include a first photoelectric conversion unit and a second photoelectric conversion unit that are stacked along the light incident direction, the first photoelectric conversion unit may include the photoelectric conversion element that receives and photoelectrically converts visible light, and the second photoelectric conversion unit may include the photoelectric conversion element that receives and photoelectrically converts infrared light.

This allows the information processing apparatus 100 to perform processing on the basis of a visible image based on the visible light and an image indicating a distance to the target object based on the infrared light.

Therefore, the information processing apparatus 100 can acquire high-definition visible information in the photoelectric conversion element in the first photoelectric conversion unit.

Moreover, in the information processing apparatus 100 as an embodiment, the imaging apparatus may include a visible signal processing unit that generates a visible image on the basis of a charge photoelectrically converted by the photoelectric conversion element in the first photoelectric conversion unit, and a distance signal processing unit that generates, on the basis of a charge photoelectrically converted by the photoelectric conversion element in the second photoelectric conversion unit, a range image indicating a distance to a target object, and the information processing unit may decide, on the basis of the visible image, whether or not the range image is captured.

This allows the information processing apparatus 100 to switch whether or not to capture the range image, depending on the target object included in the visible image.

Therefore, because the information processing apparatus 100 does not acquire the visible image in a case where it is not necessary to acquire the visible image, processing loads can be reduced.

In the information processing apparatus 100 according to the present technology described above, the imaging apparatus may include a visible signal processing unit that generates a visible image on the basis of a charge photoelectrically converted by the photoelectric conversion element in the first photoelectric conversion unit, and a distance signal processing unit that generates, on the basis of a charge photoelectrically converted by the photoelectric conversion element in the second photoelectric conversion unit, a range image indicating a distance to a target object, and the information processing unit may decide, on the basis of the range image, whether or not the visible image is captured.

This allows the information processing apparatus 100 to switch whether or not to capture the range image, depending on the target object included in the range image.

Therefore, because the information processing apparatus 100 does not acquire the range image in a case where it is not necessary to acquire the visible image, processing loads can be reduced.

Note that the effects described herein are only examples, and the effects of the present technology are not limited to these effects. Additional effects may also be obtained.

### 6. Present Technology

Note that the present technology can have the following configurations.

(1)

An imaging apparatus including
a plurality of photoelectric conversion units, each including a photoelectric conversion element that performs photoelectric conversion with light in a different wavelength region, the photoelectric conversion units being stacked in a light incident direction, and
a charge holding unit that holds charges accumulated in the photoelectric conversion elements in different the photoelectric conversion units.

(2)

The imaging apparatus according to (1), the imaging apparatus further including a charge reset unit that resets charges accumulated in the charge holding unit.

(3)

The imaging apparatus according to (1) or (2),
in which the charge holding unit holds charges accumulated in the photoelectric conversion elements disposed facing each other in the light incident direction in different the photoelectric conversion units.

(4)

The imaging apparatus according to any one of (1) to (3),
in which each of the photoelectric conversion units includes a first photoelectric conversion unit and a second photoelectric conversion unit that are stacked along the light incident direction,
the first photoelectric conversion unit includes the photoelectric conversion element using an organic material that receives and photoelectrically converts light in a specific wavelength region, and
the second photoelectric conversion unit includes the photoelectric conversion element using an inorganic material that receives and photoelectrically converts light.

(5)

The imaging apparatus according to (4), the imaging apparatus further including a charge discharging unit that discharges charges accumulated in the photoelectric conversion element in the second photoelectric conversion unit.

(6)

The imaging apparatus according to any one of (1) to (5),
in which each of the photoelectric conversion units includes a first photoelectric conversion unit and a second photoelectric conversion unit that are stacked along the light incident direction, the first photoelectric conversion unit includes the photoelectric conversion element that receives and photoelectrically converts visible light, and the second photoelectric conversion unit includes the photoelectric conversion element that receives and photoelectrically converts infrared light.

(7)

The imaging apparatus according to (6), the imaging apparatus further including a distance signal processing unit that generates, on the basis of a charge photoelectrically converted by the photoelectric conversion element in the second photoelectric conversion unit, a range image indicating a distance to a target object.

(8)

The imaging apparatus according to (6) or (7), in which the photoelectric conversion element in the second photoelectric conversion unit has a light receiving area larger than a light receiving area of the photoelectric conversion element in the first photoelectric conversion unit.

(9)

The imaging apparatus according to any one of (1) to (8), the imaging apparatus further including a drive control unit that transfers, to the charge holding unit at different timings, charges accumulated in the photoelectric conversion elements in different the photoelectric conversion units.

(10)

An information processing apparatus including
an imaging apparatus that captures an image, and
an information processing unit that executes predetermined processing on the basis of the image captured by the imaging apparatus,
in which the imaging apparatus includes
a plurality of photoelectric conversion units, each including a photoelectric conversion element that performs photoelectric conversion with light in a different wavelength region, the photoelectric conversion units being stacked in a light incident direction, and
a charge holding unit that holds charges accumulated in the photoelectric conversion element in different the photoelectric conversion units.

(11)

The information processing apparatus according to (10),
in which each of the photoelectric conversion units includes a first photoelectric conversion unit and a second photoelectric conversion unit that are stacked along the light incident direction,
the first photoelectric conversion unit includes the photoelectric conversion element that receives and photoelectrically converts visible light, and
the second photoelectric conversion unit includes the photoelectric conversion element that receives and photoelectrically converts infrared light.

(12)

The information processing apparatus according to (11),
in which the imaging apparatus includes
a visible signal processing unit that generates a visible image on the basis of a charge photoelectrically converted by the photoelectric conversion element in the first photoelectric conversion unit, and
a distance signal processing unit that generates, on the basis of a charge photoelectrically converted by the photoelectric conversion element in the second photoelectric conversion unit, a range image indicating a distance to a target object, and
the information processing unit decides, on the basis of the visible image, whether or not the range image is captured.

(13)

The information processing apparatus according to (11),
in which the imaging apparatus includes
a visible signal processing unit that generates a visible image on the basis of a charge photoelectrically converted by the photoelectric conversion element in the first photoelectric conversion unit, and
a distance signal processing unit that generates, on the basis of a charge photoelectrically converted by the photoelectric conversion element in the second photoelectric conversion unit, a range image indicating a distance to a target object, and
the information processing unit decides, on the basis of the range image, whether or not the visible image is captured.

### REFERENCE SIGNS LIST

1 Imaging apparatus
2 Imaging unit
3 Light emission unit
4 Control unit
5 Image processing unit
6 Memory
11 Pixel array unit
14 System control unit
17 Visible signal processing unit
18 Distance signal processing unit
30 First photoelectric conversion unit
30a Organic photoelectric conversion element
31 Second photoelectric conversion unit
40 Photoelectric conversion layer
41 First electrode
42 Charge accumulation electrode
43 Second electrode
100 Information processing apparatus
101 Information processing unit
FD Floating diffusion
OFG OF gate transistor

1. An imaging apparatus comprising:
a plurality of photoelectric conversion units, each including a photoelectric conversion element that performs photoelectric conversion with light in a different wavelength region, the photoelectric conversion units being stacked in a light incident direction; and
a charge holding unit that holds charges accumulated in the photoelectric conversion elements in different the photoelectric conversion units.

2. The imaging apparatus according to claim 1, the imaging apparatus further comprising a charge reset unit that resets charges accumulated in the charge holding unit.

3. The imaging apparatus according to claim 1,
wherein the charge holding unit holds charges accumulated in the photoelectric conversion elements disposed facing each other in the light incident direction in different the photoelectric conversion units.

4. The imaging apparatus according to claim 1,
wherein each of the photoelectric conversion units includes a first photoelectric conversion unit and a second photoelectric conversion unit that are stacked along the light incident direction,
the first photoelectric conversion unit includes the photoelectric conversion element using an organic material that receives and photoelectrically converts light in a specific wavelength region, and
the second photoelectric conversion unit includes the photoelectric conversion element using an inorganic material that receives and photoelectrically converts light.

5. The imaging apparatus according to claim 4, the imaging apparatus further comprising a charge discharging unit that discharges charges accumulated in the photoelectric conversion element in the second photoelectric conversion unit.

6. The imaging apparatus according to claim 1,
wherein each of the photoelectric conversion units includes a first photoelectric conversion unit and a second photoelectric conversion unit that are stacked along the light incident direction,
the first photoelectric conversion unit includes the photoelectric conversion element that receives and photoelectrically converts visible light, and
the second photoelectric conversion unit includes the photoelectric conversion element that receives and photoelectrically converts infrared light.

7. The imaging apparatus according to claim 6, the imaging apparatus further comprising a distance signal processing unit that generates, on a basis of a charge photoelectrically converted by the photoelectric conversion element in the second photoelectric conversion unit, a range image indicating a distance to a target object.

8. The imaging apparatus according to claim 6,
wherein the photoelectric conversion element in the second photoelectric conversion unit has a light receiving area larger than a light receiving area of the photoelectric conversion element in the first photoelectric conversion unit.

9. The imaging apparatus according to claim 1, the imaging apparatus further comprising a drive control unit that transfers, to the charge holding unit at different timings, charges accumulated in the photoelectric conversion elements in different the photoelectric conversion units.

10. An information processing apparatus comprising:
an imaging apparatus that captures an image; and
an information processing unit that executes predetermined processing on a basis of the image captured by the imaging apparatus,
wherein the imaging apparatus includes
a plurality of photoelectric conversion units, each including a photoelectric conversion element that performs photoelectric conversion with light in a different wavelength region, the photoelectric conversion units being stacked in a light incident direction, and
a charge holding unit that holds charges accumulated in the photoelectric conversion element in different the photoelectric conversion units.

11. The information processing apparatus according to claim 10,
wherein each of the photoelectric conversion units includes a first photoelectric conversion unit and a second photoelectric conversion unit that are stacked along the light incident direction,
the first photoelectric conversion unit includes the photoelectric conversion element that receives and photoelectrically converts visible light, and
the second photoelectric conversion unit includes the photoelectric conversion element that receives and photoelectrically converts infrared light.

12. The information processing apparatus according to claim 11,
wherein the imaging apparatus includes
a visible signal processing unit that generates a visible image on a basis of a charge photoelectrically converted by the photoelectric conversion element in the first photoelectric conversion unit, and
a distance signal processing unit that generates, on a basis of a charge photoelectrically converted by the photoelectric conversion element in the second photoelectric conversion unit, a range image indicating a distance to a target object, and
the information processing unit decides, on a basis of the visible image, whether or not the range image is captured.

13. The information processing apparatus according to claim 11,
wherein the imaging apparatus includes
a visible signal processing unit that generates a visible image on a basis of a charge photoelectrically converted by the photoelectric conversion element in the first photoelectric conversion unit, and
a distance signal processing unit that generates, on a basis of a charge photoelectrically converted by the photoelectric conversion element in the second photoelectric conversion unit, a range image indicating a distance to a target object, and
the information processing unit decides, on a basis of the range image, whether or not the visible image is captured.
